(19) United States
(12) Patent Application Publication
(10) Pub. No.: US 2025/0200412 A1
(43) Pub. Date: Jun. 19, 2025

(54) FLUX-TUNABLE READOUT RESONATORS FOR QUANTUM BITS

(71) Applicant: International Business Machines Corporation, Armonk, NY (US)

(72) Inventors: Martin O. Sandberg, Ossining, NY (US); Ted Thorbeck, Elmsford, NY (US); David C. Mckay, Ossining, NY (US)

(21) Appl. No.: 18/539,371

(22) Filed: Dec. 14, 2023

(51) Int. Cl. G06N 10/40; H10N 60/12

(52) U.S. Cl. CPC G06N 10/40; H10N 60/12

(57) ABSTRACT

A device comprises a superconducting quantum bit, and a tunable readout resonator coupled to the superconducting quantum bit. The tunable readout resonator comprises a fixed resonator and a tunable element which is coupled to the fixed resonator and which is configured for flux-tuning the tunable readout resonator into at least one of a first state and a second state. The tunable element comprises a superconducting loop which comprises at least two asymmetric Josephson junctions. In the first state, the tunable readout resonator comprises a first resonant frequency that differs from a transition frequency of the superconducting quantum bit by a first detuning value. In the second state, the tunable readout resonator comprises a second resonant frequency that differs from the transition frequency of the superconducting quantum bit by a second detuning value, which is less than the first detuning value.

### BACKGROUND

This disclosure relates generally to quantum computing and, in particular, to techniques for state readout of quantum information-storing units such as superconducting quantum bits (qubits). A quantum computing system can be implemented using a superconducting quantum processor which comprises an array of superconducting qubits, such as superconducting transmon qubits, to generate and process quantum information. Various types of quantum information processing operations (e.g., gate operations) can be performed in which superconducting qubits can be coherently controlled, placed into quantum superposition states (via, e.g., single-gate operations), exhibit quantum interference effects, and become entangled with one another (via, e.g., entanglement gate operations). Typically, quantum computing systems are configured to process quantum information that is encoded in computational basis states of the qubits, wherein gate operations are performed using the two lowest energy levels of a qubit including a ground state |0 [symbol] and a first excited state |1 [symbol] . A sin Qubit can have a basis state of |0 [symbol] or |1 [symbol] , or a linear combination of such basis states, which is known as a superposition state. In addition, quantum information can be encoded through entangled basis states of multiple qubits.

In circuit Quantum Electrodynamics (cQED), the quantum state of a given superconducting qubit state can be determined by measuring a state-dependent frequency shift of a readout resonator that is coupled to the superconducting qubit. In a conventional configuration, the readout resonator comprises a fixed resonant frequency which is detuned from a transition frequency of the superconducting qubit. The qubit-resonator system introduces an unwanted decay channel for the superconducting qubit due to the energy leakage through the readout resonator into a signal transmission line that is coupled the readout resonator, as a result of a phenomenon known as the Purcell effect. The Purcell effect is one of a plurality of limiting factors for high-fidelity qubit readout. While the Purcell rate can be suppressed by, e.g., increasing the amount of qubit-resonator detuning, this may be undesirable because increasing the amount qubit-resonator detuning results in an increase in the qubit readout measurement time, which can lead to potential errors and lower readout fidelity. In this regard, conventional qubit-resonator system configurations are designed with a trade-off between qubit relaxation time and qubit measurement time, to balance the Purcell rate with qubit measurement time.

### SUMMARY

Exemplary embodiments of the disclosure include tunable readout resonators for superconducting quantum bits, and techniques for performing readout and reset operations of superconducting quantum bits using tunable readout resonators.

For example, an exemplary embodiment includes a device which comprises a superconducting quantum bit, and a tunable readout resonator coupled to the superconducting quantum bit. The tunable readout resonator comprises a fixed resonator and a tunable element which is coupled to the fixed resonator and which is configured for flux-tuning the tunable readout resonator into at least one of a first state and a second state. The tunable element comprises a superconducting loop which comprises at least two asymmetric Josephson junctions. In the first state, the tunable readout resonator comprises a first resonant frequency that differs from a transition frequency of the superconducting quantum bit by a first detuning value. In the second state, the tunable readout resonator comprises a second resonant frequency that differs from the transition frequency of the superconducting quantum bit by a second detuning value, which is less than the first detuning value.

Advantageously, the tunable readout resonator can be flux-tuned to adjust a detuning between the tunable readout resonator and the superconducting qubit for different operating modes, which overcomes disadvantages associated with conventional readout schemes which implement a fixed detuning between a readout resonator and a superconducting qubit. For example, the tunable readout resonator can be flux-tuned to achieve the first detuning value which is configured to suppress energy leakage from the superconducting qubit through the tunable readout resonator into a transmission line coupled to the tunable readout resonator, during a readout standby mode when, e.g., gate operations are being performed on the superconducting qubit. In addition, the tunable readout resonator can be flux-tuned to achieve the second detuning value which is configured to increase a dispersive coupling between the superconducting qubit bit and the tunable readout resonator to perform, e.g., a dispersive readout operation to readout a state of the superconducting quantum bit, with high speed and high fidelity.

In another exemplary embodiment, as may be combined with the preceding paragraphs, the fixed resonator comprises a transmission line resonator or a lumped element resonator.

In another exemplary embodiment, as may be combined with the preceding paragraphs, the tunable element comprises a first Josephson junction having a first critical current, and a second Josephson junction having a second critical current, which is different from the first critical current.

In another exemplary embodiment, as may be combined with the preceding paragraphs, in the first state, the first detuning value is configured to suppress energy leakage from the superconducting quantum bit through the tunable readout resonator into a transmission line coupled to the tunable readout resonator.

In another exemplary embodiment, as may be combined with the preceding paragraphs, in the second state, the second detuning value is configured to increase a dispersive coupling between the superconducting quantum bit and the tunable readout resonator to perform a dispersive readout operation to readout a state of the superconducting quantum bit.

In another exemplary embodiment, as may be combined with the preceding paragraphs, in the second state, the second detuning value is configured to increase a coupling between the superconducting quantum bit and the tunable readout resonator to enable a parametric reset of the superconducting quantum bit by applying an alternating current drive signal to the tunable element of the tunable readout resonator.

In another exemplary embodiment, as may be combined with the preceding paragraphs, in the second state, the second detuning value is configured to increase a coupling between the superconducting quantum bit and the tunable readout resonator to increase energy leakage from the superconducting quantum bit through the tunable readout resonator into a transmission line coupled to the tunable readout resonator and thereby reset the superconducting quantum bit.

In another exemplary embodiment, as may be combined with the preceding paragraphs, the tunable element is configured for flux-tuning the tunable readout resonator into a third state in which the tunable readout resonator comprises a third resonant frequency that is detuned from a transition frequency of the superconducting quantum bit by a third detuning value, wherein the third detuning value is less than the first detuning value and greater than the second detuning value.

In another exemplary embodiment, as may be combined with the preceding paragraphs, a Purcell filter is coupled between the tunable readout resonator and an input/output transmission line, wherein in the first state, the first resonant frequency of the tunable readout resonator is in a stop band of the Purcell filter.

Another exemplary embodiment includes a system which comprises a quantum processor and a control system. The quantum processor comprises superconducting quantum bits and tunable readout resonators coupled to respective ones of the superconducting quantum bits. The control system is configured to generate control signals for controlling the superconducting quantum bits and for controlling the tunable readout resonators. At least one tunable readout resonator coupled to a given superconducting quantum bit comprises a fixed resonator and a tunable element which is coupled to the fixed resonator. The tunable element comprises a superconducting loop which comprises at least two asymmetric Josephson junctions. The tunable element is responsive to the control signals from the control system to flux tune the at least one tunable readout resonator into at least one of a first state and a second state. In the first state, the at least one tunable readout resonator comprises a first resonant frequency which differs from a transition frequency of the given superconducting quantum bit by a first detuning value. In the second state, the at least one tunable readout resonator comprises a second resonant frequency which differs from the transition frequency of the given superconducting quantum bit by a second detuning value, which is less than the first detuning value.

Another exemplary embodiment includes a method which comprises applying a control signal to a tunable readout resonator which is coupled to a superconducting quantum bit, the tunable readout resonator comprising a fixed resonator and a tunable element which is coupled to the fixed resonator and which is responsive to the control signal to flux-tune the tunable readout resonator into at least one of a first state and a second state, the tunable element comprising a superconducting loop which comprises at least two asymmetric Josephson junctions. In the first state, the tunable readout resonator comprises a first resonant frequency which differs from a transition frequency of the superconducting quantum bit by a first detuning value. In the second state, the tunable readout resonator comprises a second resonant frequency which differs from the transition frequency of the superconducting quantum bit by a second detuning value, which is less than the first detuning value.

Other embodiments will be described in the following detailed description of exemplary embodiments, which is to be read in conjunction with the accompanying figures.

### BRIEF DESCRIPTION OF THE DRAWINGS

FIG. 1A schematically illustrates a quantum system which implements a tunable readout resonator, according to an exemplary embodiment of the disclosure.

FIG. 1B schematically illustrates a quantum system which implements a tunable readout resonator, according to another exemplary embodiment of the disclosure.

FIG. 2 schematically illustrates a quantum system which implements a tunable readout resonator, according to another exemplary embodiment of the disclosure.

FIG. 3 graphically illustrates a tuning curve for flux-tuning a tunable readout resonator, according to an exemplary embodiment of the disclosure.

FIG. 4 illustrates a flow diagram of a method for controlling a tunable readout resonator to perform qubit readout and qubit reset operations, according to an exemplary embodiment of the disclosure.

FIG. 5 schematically illustrates readout circuitry of a quantum processing system in which a tunable readout resonator is implemented to perform qubit readout and qubit reset operations, according to an exemplary embodiment of the disclosure.

FIG. 6 schematically illustrates a quantum processing system comprising control circuitry that configured for controlling tunable readout resonators to perform qubit readout and qubit reset operations, according to an exemplary embodiment of the disclosure.

FIG. 7 schematically illustrates an exemplary architecture of a computing environment for hosting a quantum computing platform, according to an exemplary embodiment of the disclosure.

### DETAILED DESCRIPTION

Exemplary embodiments of the disclosure will now be described in further detail with regard to tunable readout resonators for superconducting quantum bits, and techniques for performing quantum bit readout and reset operations using tunable readout resonators.

It is to be understood that the various features shown in the accompanying drawings are schematic illustrations that are not drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the term “exemplary” as used herein means “serving as an example, instance, or illustration.” Any embodiment or design described herein as “exemplary” is not to be construed as preferred or advantageous over other embodiments or designs.

Further, it is to be understood that the phrase “configured to” as used in conjunction with a circuit, structure, element, component, or the like, performing one or more functions or otherwise providing some functionality, is intended to encompass embodiments wherein the circuit, structure, element, component, or the like, is implemented in hardware, software, and/or combinations thereof, and in implementations that comprise hardware, wherein the hardware may comprise quantum circuit elements (e.g., quantum bits, coupler circuitry, etc.), discrete circuit elements (e.g., transistors, inverters, etc.), programmable elements (e.g., application specific integrated circuit (ASIC) chips, field-programmable gate array (FPGA) chips, etc.), processing devices (e.g., central processing units (CPUs), graphics processing units (GPUs), etc.), one or more integrated circuits, and/or combinations thereof. Thus, by way of example only, when a circuit, structure, element, component, etc., is defined to be configured to provide a specific functionality, it is intended to cover, but not be limited to, embodiments where the circuit, structure, element, component, etc., is comprised of elements, processing devices, and/or integrated circuits that enable it to perform the specific functionality when in an operational state (e.g., connected or otherwise deployed in a system, powered on, receiving an input, and/or producing an output), as well as cover embodiments when the circuit, structure, element, component, etc., is in a non-operational state (e.g., not connected nor otherwise deployed in a system, not powered on, not receiving an input, and/or not producing an output) or in a partial operational state.

As is known in the art, quantum computing provides a computing paradigm which utilizes fundamental principles of quantum mechanics to perform computations. Quantum computing algorithms and applications are defined using quantum circuits. A quantum circuit is a computational routine which defines coherent quantum operations that are performed on quantum data that is stored in quantum bits, in conjunction with operations that are performed using classical computation. Quantum circuits are utilized to define complex algorithms and applications in an abstract manner, which can be executed on a quantum computer. In a quantum computer, primitive operations comprise gate operations (e.g., single-qubit gate operations, two-qubit gate operations, multi-qubit gate operations (e.g., 3 or more qubits) that are applied to qubits, to perform quantum computing operations for a given application. The quantum circuits allow a quantum computer to receive classical data, perform quantum operations based on the received data, and output a classical solution.

As noted above, a single qubit can have a computation basis state of |0 [symbol] (ground state) or |1 [symbol] (first excited state), or a linear combination of such basis states, which is known as a superposition state. As is known in the art, the state of a qubit can be graphically represented as a point on unit sphere (radius=1), which is called the Bloch sphere, with X, Y, and Z axes. The basis state |0 [symbol] (referred to as ground state) of a qubit is represented at a point (north pole) on a positive Z-axis of the Bloch sphere, while the basis state or |1 [symbol] (referred to as first excited state) of a qubit is represented at a point (south pole) on a negative Z-axis of the Bloch sphere. A superposition state |ψ [symbol] of the qubit can be represented as a point on the Bloch sphere as follows:

$$\vert ψ 〉 = cos \frac{θ}{2} \vert 0 〉 + {e}^{i ϕ} sin \frac{θ}{2} \vert 1 〉 ,$$

where the terms

$$cos \frac{θ}{2} and sin \frac{θ}{2}$$

correspond to the amplitude probabilities associated with the respective states |0 [symbol] and |1 [symbol] , and wherein the term e^{iϕ} corresponds to a relative phase between the states |0 [symbol] and |1 [symbol] . The position of a point on the Bloch sphere representing a superposition state of a qubit is determined based on the angles θ and ϕ. The angle θ represents the angle from the positive Z axis (the |0 [symbol] state) to the positive X axis on the X-Z plane, where 0≤θ≤π. The angle ϕ represents the angle from the positive X axis (the |+) state) to the positive Y axis on the X-Y plane, where 0≤θ≤2π. The angle θ influences the probability of observing a qubit state of |0 [symbol] or |1 [symbol] when the qubit is read, wherein the probability of reading a qubit state of |1 [symbol] increases as θ increases. The angle ϕ influences the relative phase between the states |0 [symbol] and |1 [symbol] . The state of a given qubit can be changed by applying a single-qubit gate operation to the given qubit, which causes the current state of the qubit to rotate around, e.g., the X-axis, Y-axis, and/or Z-axis, etc., depending on the given gate operation. A rotation about the Z-axis results in a change in the angle ϕ.

The state of a given qubit can be changed by applying a single-qubit gate operation to the given qubit, which causes the current state of the qubit to rotate around, e.g., the X-axis, Y-axis, and/or Z-axis, etc., depending on the given gate operation. A rotation about the Z-axis results in a change in the angle ϕ. In addition, qubits can be controlled using entanglement gate operations to entangle the states of two or more qubits and, thereby, generate a combined state of two or more qubits, which contains more information than the individual states of the qubits. Entanglement allows multiple qubits in a superposition to be correlated with each other in a way that the state of one qubit can depend on the state of another qubit such that more information can be encoded with multiple entangled qubits as compared to encoding the qubits individually. Accordingly, quantum information processing, based on principles of superposition and entanglement states of qubits, allows quantum computers to solve difficult problems that are intractable using conventional computers.

Quantum information processing with superconducting qubits requires that the qubits are well isolated from their environment, while being able to precisely manipulate the quantum states of qubits (via gate operations) and precisely and rapidly readout and measure the quantum states of the qubits with high-fidelity and low rates of error. A common method for measuring a qubit (addressable two-level system) includes dispersively coupling the qubit to a linear readout resonator (or bus resonator) and performing a readout operation to measure the state of the qubit. In a dispersive readout regime, the qubit states |0 [symbol] and |1 [symbol] cause different shifts in the resonance frequency of the readout resonator, wherein the shift in frequency is determined by measuring the phase of a microwave pulse reflected from or transmitted through the readout resonator.

More specifically, in a dispersive regime of qubit-resonator coupling, a readout control signal (e.g., microwave signal with a requisite frequency tone, pulse envelope shape, and pulse duration) is applied to the linear readout resonator, and the readout control signal interacts with the given qubit/resonator system in a manner which results in the generation of a resulting readout signal that is reflected out from the readout resonator, wherein the readout signal comprises information (e.g., phase and/or amplitude) that is qubit-state dependent. In other words, the dispersive readout process yields a readout signal having a state-dependent phasor response, which is analyzed to discriminate the quantum state of the superconducting qubit.

In the dispersive regime, the transition frequency of the qubit is far detuned from the resonant frequency of the readout resonator, such that that frequency of the readout resonator is weakly dependent on the state of the qubit. Such detuning is designed to decouple the qubit from a readout transmission line which is coupled to the readout resonator and thereby minimize a Purcell decay channel, and thereby decrease the probability of qubit relaxation through the readout resonator via a Purcell decay process. On the other hand, fast and high-fidelity readout of the qubit state requires strong coupling between the resonator and environment, which leads to conflicting requirements of the properties of the readout resonator with regard to efficient readout and qubit isolation.

The Hamiltonian for the qubit-resonator system is expressed as:

$$H = {w}_{0} {n}_{0} + \frac{{α}_{0} {n}_{0} ( {n}_{0} - 1 )}{2} + {g}_{0} ( {a}_{0} + {a}_{0}^{†} ) ( {b}_{0} + {b}_{0}^{†} ) + {w}_{BUS} {b}_{i}^{†} {b}_{i} ,$$

where w₀ denotes the transition frequency of the qubit, w_{BUS} denotes the resonant frequency of the resonator, g₀ denotes the qubit-resonator coupling, α₀ denotes the qubit anharmonicity, a₀ denotes the annihilation operator for the qubit, and b₀ denotes the annihilation operator for the resonator. The expression g₀(a₀+a₀^{†})(b₀+b₀^{†}) denotes the coupling from the qubit to the bus (readout resonator).

The measurement Hamiltonian in the dispersive limit is expressed as:

$$H = {w}_{0} {n}_{0} + \frac{{α}_{0} {n}_{0} ( {n}_{0} - 1 )}{2} + {W}_{BUS} ( 1 + 2 χ {n}_{0} ) {b}_{i}^{†} {b}_{i} ,$$

where χ denotes a dispersive coupling factor. The dispersive coupling factor χ is defined as:

$$χ = \frac{{g}_{0}^{2}}{2 Δ} \cdot \frac{2 α}{Δ} ,$$

where Δ=w₀−w_{BUS}, denotes the detuning between the transition frequency of the qubit and the resonant frequency of the readout resonator. The dispersive coupling factor χ determines how large the frequency shift of the readout resonator will be, depending on the state of the qubit.

In a steady state, an optimal measurement occurs when κ=2χ with a signal-to-noise ratio (SNR) (quantum efficiency set to unity) of:

$$\frac{4 {nT}_{m} χ}{2 π} ,$$

where κ denotes a coupling rate (or decay rate) of the readout resonator to an I/O transmission line (i.e., the resonator energy damping rate mainly due to coupling to the transmission line), where n denotes a number of photons in steady state, and where Tₘ denotes a measurement time. Therefore, increasing the values of κ, χ is important for measurement fidelity and speed. However, in the absence of a Purcell filter, there are limits to increasing κ and since it affects the relaxation time, T1, of the qubit, wherein the relaxation time T1 of a given qubit denotes the time needed for the time needed for the given qubit to spontaneously decay from the first excited state to the ground state. In this regard, measuring the state of a superconducting qubit introduces a loss channel which can enhance spontaneous emission through the Purcell effect, thus decreasing qubit lifetime.

More specifically, with a dispersive measurement process, the decay channel of the readout resonator increases the decay rate of the qubit, where the qubit decays with a Purcell rate γ_{q} expressed as:

$${γ}_{q} \approx κ \cdot \frac{{g}_{0}^{2}}{{Δ}^{2}} .$$

In this regard, a higher κ results in a decrease in the relaxation time of the qubit. In this regard, the detuning Δ is selected so that the maximum coherence time imposed by the Purcell effect

$$\frac{1}{{γ}_{q}}$$

exceeds the relation time T1 of the qubit due to other dissipation.

On the other hand, a greater Purcell decay leads to measurement error and, consequently, it is important to reduce the Purcell rate. This can be done by decreasing the value of χ, but at the cost of increasing the necessary measurement time Tₘ. The Purcell decay can be decreased by decreasing the leakage rate κ, but also at the cost of increasing the necessary measurement time Tₘ. In this regard, increasing the amount of filtering provided by the readout resonator results in increasing the readout measurement time and decreasing the readout fidelity.

Moreover, as κ increases, the same process which allows a high-fidelity measurement can also result in an increase in the rate of dephasing of the qubit when there are photons in the cavity (readout resonator). In addition to the relaxation time T1, quantum decoherence is characterized by a dephasing time T2, which is defined as the elapsed time before the resonance frequency of a given qubit becomes unidentified. At the 2χ=κ point for small number (n) of photons, the dephasing rate of the qubit is given by

$${T}_{2} = \frac{2}{n χ} .$$

Exemplary embodiments of the disclosure implement qubit readout schemes which utilize tunable readout resonators which can be flux-tuned to adjust a detuning between a readout resonator and a superconducting qubit for different operating modes (e.g., standby mode, readout mode, and reset mode). The exemplary qubit readout schemes overcome the disadvantages associated with conventional readout schemes which implement a fixed detuning between a readout resonator and a superconducting qubit, which requires a compromise between Purcell loss (leakage of qubit energy through the resonator) and readout speed. In contrast, the exemplary readout schemes discussed herein implement a tunable readout resonator that can be flux-tuned to, e.g., achieve (i) a first qubit-resonator detuning which is configured to suppress energy leakage from a superconducting qubit through the tunable readout resonator into a transmission line coupled to the tunable readout resonator, during a readout standby mode when, e.g., gate operations are being performed on the superconducting qubit, and (ii) a second qubit-resonator detuning which is configured to increase a dispersive coupling between the superconducting qubit bit and the tunable readout resonator to perform a dispersive readout operation to readout a state of the superconducting quantum bit, with high speed and high fidelity.

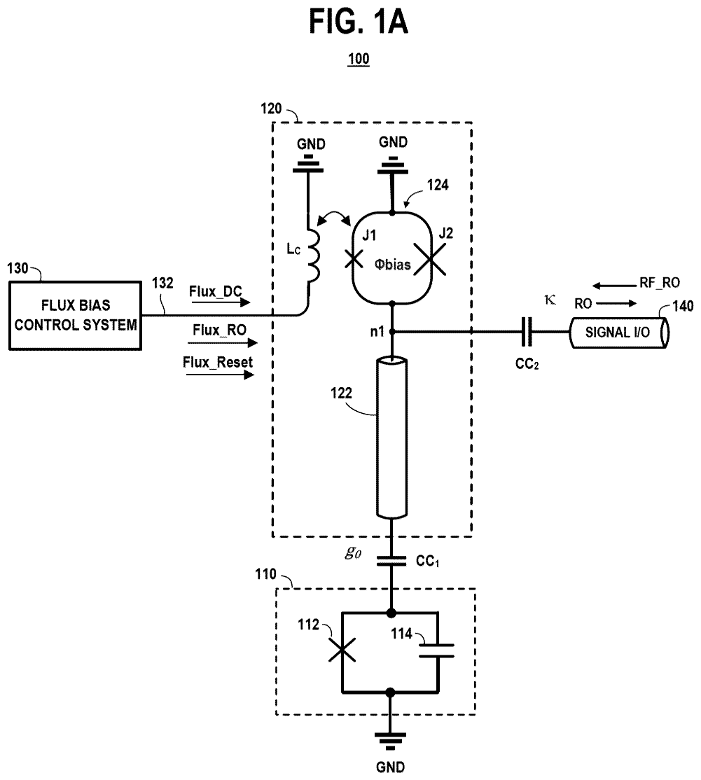

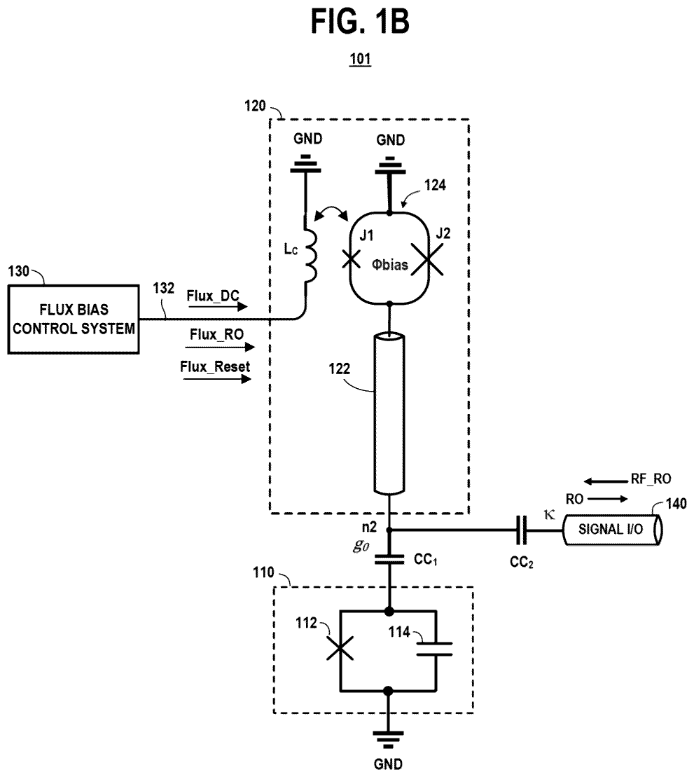

FIG. 1A schematically illustrates a system which implements a tunable readout resonator, according to an exemplary embodiment of the disclosure. In particular, FIG. 1 schematically illustrates a quantum system 100 which comprises a superconducting qubit 110, a tunable readout resonator 120, a flux bias control system 130, and a readout signal input/output (I/O) transmission line 140. The tunable readout resonator 120 is coupled to the superconducting qubit 110 via a coupling capacitor CC₁ with a coupling strength g₀. The tunable readout resonator 120 is coupled to the signal I/O transmission line 140 via a coupling capacitor CC₂ with a coupling strength κ.

In the exemplary embodiment of FIG. 1A, the superconducting qubit 110 comprises a fixed-frequency transmon qubit having a Josephson junction 112 and capacitor 114 coupled in parallel. In other embodiments, the quantum system 100 can be implemented using other types of superconducting qubits such as fluxonium qubits, multimode qubits (e.g., two-junction qubits, or tunable coupling qubits), and other types of fixed-frequency qubits, or tunable-frequency qubits.

The tunable readout resonator 120 comprises a fixed resonator 122 and a tunable element 124 coupled to the fixed resonator 122. The tunable element 124 comprises a superconducting loop which comprises at least two asymmetric Josephson junctions including a first Josephson junction J1 and a second Josephson junction J2. In the exemplary embodiment of FIG. 1A, the tunable element 124 comprises an asymmetric DC superconducting quantum interference device (SQUID), wherein the first Josephson junction has a first critical current I_{C1}, and the second Josephson junction J2 has a second critical current I_{C2}, which is different from the first critical current I_{C1}. For example, in an exemplary embodiment, the second critical current I_{C2} is greater than the first critical current I_{C1} by a factor of 2.

In alternate embodiments, the fixed resonator 122 comprises a transmission line resonator or a lumped element resonator. For example, in some embodiments, the fixed resonator 122 is a transmission line resonator comprising a quarter-wavelength coplanar waveguide (CPW) transmission line (e.g., CPW resonator), which is terminated/shunted to ground (GND) via the tunable element 124. In some embodiments, the tunable element 124 is coupled to a point of the transmission line resonator where there is high current in the transmission line. In the exemplary embodiment of FIG. 1A, the tunable element 124 is coupled to the fixed resonator 122 at node n1, which is an I/O node of the tunable readout resonator 120 which is coupled to the signal I/O transmission line 140. The tunable element 124 (e.g., asymmetric DC SQUID) can be viewed as an inductor element having a tunable inductance L_{S} that can be tuned by changing a magnitude of a magnetic flux bias Φ_{bias} that is threaded through the superconducting loop of the tunable element 124.

In this regard, the tunable element 124 (e.g., asymmetric DC SQUID) serves as a tunable inductor, wherein the inductance can be varied by a magnetic flux bias applied to the tunable element 124, to change the inductance of the tunable readout resonator 120 and thus change the resonant frequency of the tunable readout resonator 120. For example, assuming the tunable element 124 comprises an asymmetric DC SQUID having an critical current I_{CS}=(I_{C1}+I_{C2}), the inductance L_{S} of the tunable element 124 is expressed as:

$${L}_{S} = \frac{{Φ}_{0}}{4 π {I}_{CS} \vert cos ( \frac{π Φ}{{Φ}_{0}} ) \sqrt{1 + {d}^{2} {tan}^{2} ( \frac{π Φ}{{Φ}_{0}} )} \vert} ,$$

where d denotes a magnitude of the asymmetry of the critical currents of the Josephson junctions J1 and J2 (where d=|(I_{C1}−I_{C2})/(I_{C1}+I_{C2})|), and where Φ₀ denotes the magnetic flux quantum, Φ₀=h/(2e)≈2.07×10⁻¹⁵ Weber (volt-seconds), where h is Planck's constant, and e denotes the magnitude of electron charge. As is known in the art, magnetic flux quantum Φ₀ is a fundamental unit of superconducting magnetic flux which represents a quantization of magnetic flux threading a superconducting loop.

It is to be noted the term “fixed resonator” as used herein refers to a resonator such as an LC resonator having fixed inductance L and capacitance C parameters. For example, a transmission line resonator comprises a fixed inductance L per unit length (e.g., 400 nH/m) and a fixed capacitance C per unit length (e.g., 150 pF/m), providing a fixed total amount of inductance L and capacitance C over a given length of the transmission line. For the exemplary tunable readout resonator 120 of FIG. 1A, the fixed resonator 122 provides a fundamental resonant frequency for the tunable readout resonator 120, while the tunable element 124 comprises a tunable inductance which adds additional variable inductance to adjust the resonant frequency of the tunable readout resonator 120. In an exemplary embodiment, the variable inductance provided by the tunable element 124 provides a fraction of the total inductance of the tunable readout resonator as provided by the fixed resonator 122.

As schematically illustrated in FIG. 1A, the flux bias control system 130 is configured to generate and apply flux bias control signals (e.g., Flux_DC, Flux_RO, Flux_Reset) on a control line 132. The control line 132 comprises a coupling inductor Lc that is disposed adjacent and in proximity to the tunable element 124. The coupling inductor Lc generates a magnetic flux bias Φ_{bias} based on a given flux bias control signal applied on the control line 132, wherein the magnetic flux bias Φ_{bias} is threaded through the superconducting loop of the tunable element 124 which, in turn, tunes the resonant frequency of the tunable readout resonator 120. The resonant frequency of the tunable readout resonator 120 is varied for different operating modes (e.g., standby mode, readout mode, and reset mode) to adjust the detuning between the tunable readout resonator 120 and the superconducting qubit 110 for the different operating modes.

For example, the flux bias control system 130 applies a first flux bias control signal, Flux_DC, on the control line 132 to provide a fixed magnetic flux bias to the tunable element 124. More specifically, in some embodiments, the flux bias control signal Flux_DC comprises a fixed DC current that may be applied to the control line 132 to ensure that the net amount of magnetic flux bias Φ_{bias} that is threaded through the superconducting loop of the tunable element 124 is zero (0) or substantially zero, i.e., Φ_{bias}≅0. For example, the flux bias control signal Flux_DC can be applied to add a small amount of fixed magnetic flux bias to compensate for any trapped flux (earth magnetic field) in the superconducting loop of the tunable element 124.

When the net amount of magnetic flux bias Φ_{bias} threaded through the superconducting loop of the tunable element 124 is Φ_{bias}≅0, the tunable element 124 is in a lowest inductance state and, consequently, the resonant frequency of the tunable readout resonator 120 is at a highest resonant frequency. In this state, there is a relatively large magnitude of detuning between the resonant frequency of the tunable readout resonator 120 and the transition frequency of the superconducting qubit 110, which serves to suppress energy leakage from the superconducting qubit 110 through the tunable readout resonator 120 into the signal I/O transmission line 140 coupled to the tunable readout resonator 120. In this instance, the quantum computing system 100 can be considered to be in a standby mode of operation (with regard to qubit readout), wherein one or more gate operations can be applied to the superconducting qubit 110 during execution of a quantum computing algorithm to manipulate the quantum state of the superconducting qubit 110. In the standby mode of operation, the tunable readout resonator 120 is detuned far from the superconducting qubit 110 so that the tunable readout resonator 120 provides significant filtering to suppress the Purcell decay (energy leakage) of the superconducting qubit 110 through the tunable readout resonator 120 into the signal I/O transmission line 140.

To perform a dispersive readout operation to readout the quantum state of the superconducting qubit 110, the flux bias control system 130 applies a second flux bias control signal, Flux_RO, on the control line 132 (e.g., on top of the fixed Flux_DC control signal) to place the quantum system 100 into a readout mode of operation. The flux bias control signal Flux_RO is configured to cause a decrease in the detuning between the tunable readout resonator 120 and the superconducting qubit 110 to facilitate a high-fidelity and fast readout of the quantum state of the superconducting qubit 110.

More specifically, in some embodiments, the flux bias control signal Flux_RO comprises a control pulse (e.g., a current pulse) that is asserted for a given duration to increase an amount of magnetic flux bias Φ_{bias} that is threaded through the superconducting loop of the tunable element 124 which, in turn, causes an increase in the inductance of the tunable element 124 and, consequently, a decrease in the resonant frequency of the tunable readout resonator 120. In this state of the tunable readout resonator 120, the amount of detuning between the resonant frequency of the tunable readout resonator 120 and the transition frequency of the superconducting qubit 110 is decreased (as compared to the standby mode), which serves to increase the dispersive coupling χ and thereby enable a fast readout operation.

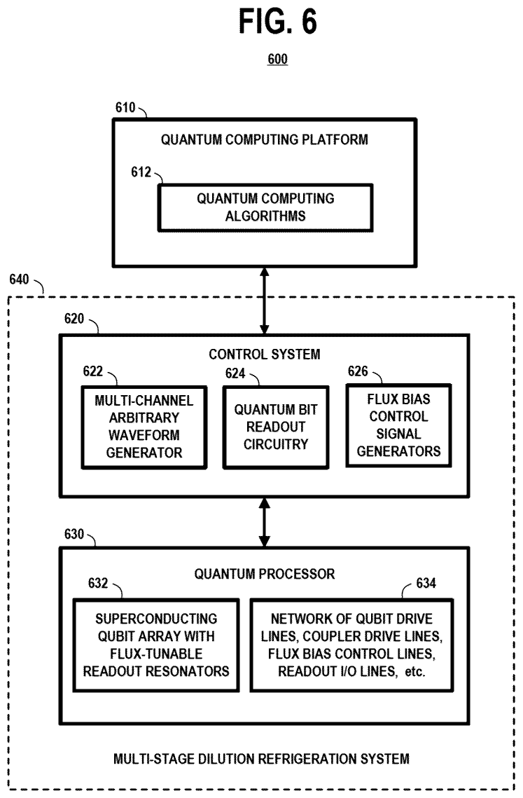

As schematically illustrated in FIG. 1A, in the readout operation mode, a dispersive readout process is performed by applying a control pulse (denoted RF_RO) to the qubit-readout resonator system by the signal I/O transmission line 140. In response to the control pulse RF_RO, a resulting readout signal RO is reflected out from the tunable readout resonator 120 onto the signal I/O transmission line 140. The readout signal RO comprises information (e.g., phase and/or amplitude) that is qubit-state dependent, wherein the readout signal RO is further processed by readout circuitry (e.g., FIG. 6) to measure the quantum state of the superconducting qubit 110.

Furthermore, in some embodiments, the flux bias control system 130 applies a third flux bias control signal, Flux_Reset, on the control line 132 (e.g., on top of the fixed Flux_DC control signal) to place the quantum system 100 into a qubit reset mode of operation, which is configured to enable a reset of the superconducting qubit 110 by removing an excited state (e.g., first excited state |1 [symbol] ) and thereby return the superconducting qubit 110 to a target reset state, e.g., a ground state |0 [symbol] . The reset of the superconducting qubit 110 can be performed using different techniques.

For example, in some embodiments, the flux bias control signal Flux_Reset comprises reset control pulse (e.g., current pulse) that is asserted for a given duration to increase an amount of magnetic flux bias Φ_{bias} that is threaded through the superconducting loop of the tunable element 124 to increase in the inductance of the tunable element 124 and, consequently, a decrease the resonant frequency of the tunable readout resonator 120. In this state of the tunable readout resonator 120, the amount of detuning between the resonant frequency of the tunable readout resonator 120 and the transition frequency of the superconducting qubit 110 is decreased to a relatively small amount of detuning which serves to increase the dispersive coupling factor χ. As a result of the lower detuning, the tunable readout resonator 120 is driven into near resonance with the superconducting qubit 110, which increases the Purcell decay rate and causes a spontaneous relaxation of the superconducting qubit 110 after a given amount of time via dissipation of the qubit energy through the tunable readout resonator 120.

In other embodiments, a parametric reset operation is performed to reset the superconducting qubit 110 to the ground state by swapping the excitation of the superconducting qubit 110 to the tunable readout resonator 120, which is then dissipated through the tunable readout resonator 120. For example, in some embodiments, the flux bias control signal Flux_Reset is configured to parametrically drive magnetic flux through the superconducting loop of the tunable element 124 to cause an excitation to swap from the superconducting qubit 110 to the tunable readout resonator 120. In particular, in some embodiments, this reset process involves driving a sideband transition by applying an AC flux bias control signal Flux_Reset to modulate the flux through the tunable element 124 of the tunable readout resonator 120 at the decreased qubit-coupler detuning frequency (e.g., 500 MHz). The parametric reset operation induces a swapping of the excited state of the superconducting qubit 110 into the tunable readout resonator 120 to cause fast relaxation of the superconducting qubit 110.

FIG. 1B schematically illustrates a system which implements a tunable readout resonator, according to another exemplary embodiment of the disclosure. In particular, FIG. 1B schematically illustrates a quantum system 101 which is similar in architecture and operation as the quantum system 100 of FIG. 1A. However, in the quantum system 101 of FIG. 1B, the I/O node of the tunable readout resonator 120 is coupled at node n2 to the superconducting qubit 110 and the signal I/O transmission line 140.

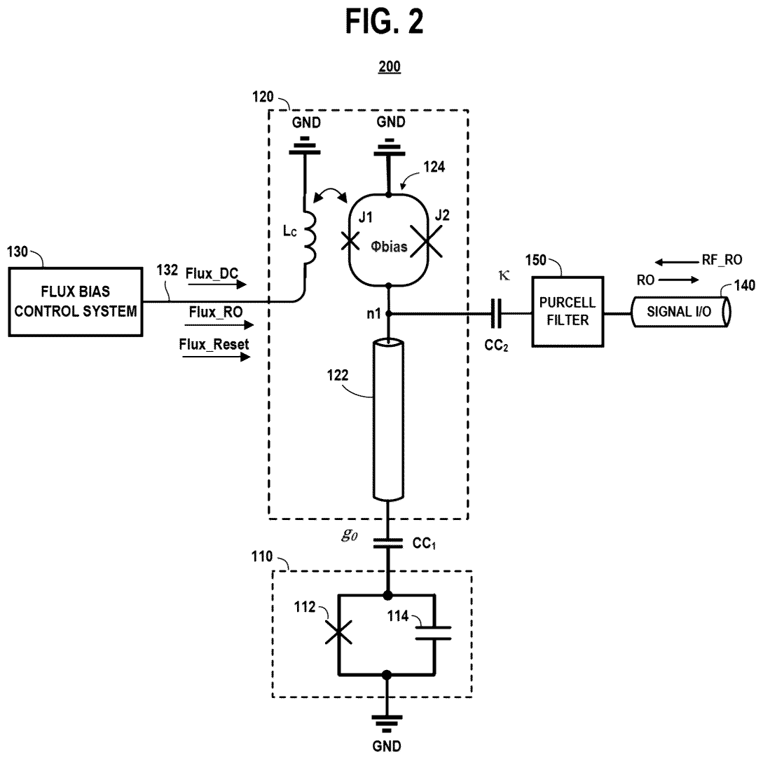

FIG. 2 schematically illustrates a system which implements a tunable readout resonator, according to another exemplary embodiment of the disclosure. In particular, FIG. 2 schematically illustrates a quantum system 200 which is similar in architecture and operation as the quantum system 100 of FIG. 1A. However, the quantum system 200 of FIG. 2 further comprises a Purcell filter 150 coupled between the I/O node (e.g., node n1) of the tunable readout resonator 120 and the signal I/O transmission line 140. In some embodiments, the Purcell filter 150 comprises a bandpass filter that is configured to suppress signal propagation at the transition frequency of the superconducting qubit 110 (and thereby suppress spontaneous emission of the qubit energy through the Purcell effect), while allowing signal propagation at the readout signal frequency.

Furthermore, in some embodiments, when the quantum system 200 is in a standby mode, as noted above, the net amount of magnetic flux bias Φ_{bias} threaded through the superconducting loop of the tunable element 124 is Φ_{bias}≅0, and the tunable element 124 is in a lowest inductance state such that a resonant frequency of the tunable readout resonator 120 is at its highest resonant frequency. The Purcell filter 150 can be configured such that the resonant frequency of the tunable readout resonator 120 in the standby state falls within the stop band of the Purcell filter 150, while the resonant frequency of the tunable readout resonator 120 in the readout state falls within the passband of the Purcell filter 150. In this configuration, in the standby state, the Purcell filter 150 is configured to protect the tunable readout resonator 120 from noise from the readout signal chain, as well as protect the superconducting qubit 110 from Purcell loss. In other words, in some embodiments, the Purcell filter 150 is configured to suppresses signal propagation at the transition frequency of the superconducting qubit 110, as well as suppress signal propagation at the resonant frequency of the tunable readout resonator 120 when tuned in the standby state.

In other embodiments, the Purcell filter 150 can be configured such that the high frequency point of the tunable readout resonator 120 falls within the pass band of the Purcell filter 150, while the low frequency point of the tunable readout resonator 120 falls within the stop band of the Purcell filter 150. In this configuration, the tunable readout resonator can be loaded with photons at the high frequency point, and then pulsed to the lower frequency point to disperse before returning to the high frequency point to release the photons. In this instance, the photons are prevented from decaying from the readout resonator when the resonant frequency is outside the Purcell filter band and will hence remain stored in the readout resonator during the operation. The phase of the photons that are stored during the readout tuning will depend on the state of the qubit, and can be detected by comparing to a reference signal.

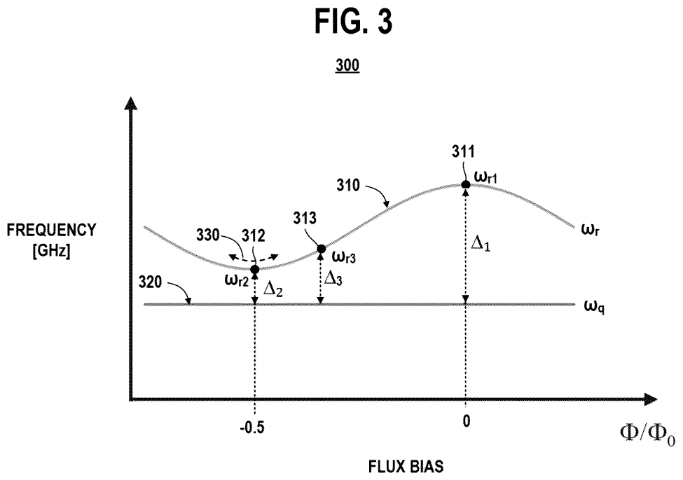

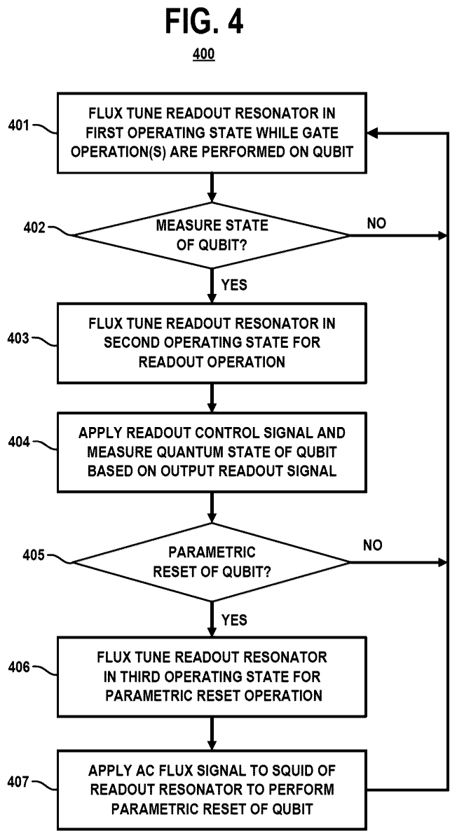

Exemplary modes of operation of the quantum systems shown in FIGS. 1A, 1B, and 2 will now be discussed in further detail with regard to FIGS. 3 and 4. For example, FIG. 3 graphically illustrates a tuning curve for flux-tuning a tunable readout resonator, according to an exemplary embodiment of the disclosure. In particular, FIG. 3 is a graph 300 which illustrates a tuning curve 310 of a tunable readout resonator having a same or similar architecture of the tunable readout resonator 120 shown in FIGS. 1A, 1B, and 2. For illustrative purposes, FIG. 3 will be discussed in further detail with regard to the tunable readout resonator 120 of FIGS. 1A, 1B, and 2. The tuning curve 310 represents a varying resonant frequency ωᵣ (e.g., GHz) of the tunable readout resonator 120 as a function of magnetic flux bias

$$( e . g . , \frac{Φ}{{Φ}_{0}} )$$

that is threaded through the superconducting loop of the tunable element 124 (e.g., the asymmetric DC SQUID). Moreover, the graph 300 illustrates a curve 320 which represents a fixed transition frequency ω_{q} (e.g., GHz) of a superconducting qubit, e.g., a fixed-frequency transmon superconducting qubit 110 as shown in FIGS. 1A, 1B, and 2).

In addition, FIG. 3 illustrates three different points 311, 312, and 313 on the tuning curve 310, which represent different tuning states and associated operating modes of the tunable readout resonator 120. The first point 311 (alternatively referred to herein as the “high frequency point” or the “upper sweet spot”) corresponds to a first resonant frequency ωᵣ₁ of the tunable readout resonator 120 when tuned in a first state (e.g., standby state, or “off” state) with a magnetic flux bias Φ=0 or substantially zero (0). In the first state, the first resonant frequency ωᵣ₁ of the tunable readout resonator 120 differs from the transition frequency ω_{q} of the superconducting qubit 110 by a first detuning value Δ₁, where Δ₁=ωᵣ₁−ω_{q}.

The second point 312 (alternatively referred to herein as the “low frequency point” or the “lower sweet spot”) corresponds to a second resonant frequency ωᵣ₂ of the tunable readout resonator 120 when tuned in a second state (e.g., readout state, or reset state, or “on” state) with a net amount of magnetic flux bias Φ≅−0.50 Φ₀. In the second state, the second resonant frequency ωᵣ₂ of the tunable readout resonator 120 differs from the transition frequency ω_{q} of the superconducting quantum bit by a second detuning value Δ₂, where Δ₂=ωᵣ₂−ω_{q}. In an exemplary embodiment, Δ₂<<Δ₁.

As schematically illustrated in FIG. 3, when a magnetic flux bias Φ=0 is threaded through the superconducting loop of the tunable element 124 (e.g., asymmetric DC SQUID) of the tunable readout resonator 120, the tunable element 124 is in a lowest inductance state and, consequently, the tunable readout resonator 120 is at the highest resonant frequency ωᵣ₁ of the tuning curve 310. In this state, the relatively large magnitude of the first detuning value Δ₁=ωᵣ₁−ω_{q} between tunable readout resonator 120 and the superconducting qubit 110 serves to suppress Purcell decay (energy leakage) of the superconducting qubit 110 through the tunable readout resonator 120.

On the other hand, when a magnetic flux bias Φ≅−0.50 Φ₀ is threaded through the superconducting loop of the tunable element 124 (e.g., asymmetric DC SQUID) of the tunable readout resonator 120, the tunable element 124 is in a highest inductance state and, consequently, the tunable readout resonator 120 is at the lowest resonant frequency ωᵣ₂ of the tuning curve 310. In this state, the relatively small magnitude of the second detuning value Δ₂=ωᵣ₂−ω_{q} between tunable readout resonator 120 and the superconducting qubit 110 serves to increase the dispersive coupling factor χ and thereby enable a fast readout operation, or otherwise enable a qubit reset by performing a parametric reset operation, or wait for a sufficient period of time to allow a spontaneous relaxation of the superconducting qubit 110 due to the increased Purcell decay rate that is achieved as a result of the relatively small detuning value Δ₂=ωᵣ₂−ω_{q}.

With regard to performing a parametric reset of the superconducting qubit 110, as noted above, a Flux_Reset signal (AC drive signal) can be applied to the tunable readout resonator 120 to modulate the magnetic flux that is threaded through the superconducting loop of the tunable element 124, which results in modulating the resonant frequency of the tunable readout resonator 120 around the lower frequency point 312, which is schematically illustrated in FIG. 3 by the double-ended curved arrow 330. This causes a parametric swapping of an excited state of the superconducting qubit 110 into the tunable readout resonator 120 (which then dissipates the energy), to thereby reset the state of the superconducting qubit 110 to a ground state.

It is to be appreciated that the implementation of the tunable element 124 with asymmetric Josephson junctions J1 and J2 (e.g., asymmetric DC SQUID) prevents the resonant frequency ωᵣ of the tunable readout resonator 120 from being tuned to ωᵣ=0. Instead, as illustrated in FIG. 3, the first and second points 311 and 312 on the tuning curve 310 are points at which the slope (or first derivative) of the tuning curve 310 is zero (0). In this regard, the first point 311 and the second point 312 on the tuning curve 310 represent states of the tunable readout resonator 120 which are insensitive to flux noise (e.g., flux insensitive tuning points). The tunable readout resonator 120 is tuned to the high frequency point 311 when not performing a qubit readout operation or a qubit reset operation to ensure that the superconducting qubit 110 and tunable readout resonator 120 are far detuned (Δ₁=ωᵣ₁−ω_{q}) to suppress leakage of the qubit state. On the other hand, the tunable readout resonator 120 can be tuned to the low frequency point 312 to perform a qubit readout operation or a qubit reset operation, wherein the relatively small detuning value Δ₂=ωᵣ₂−ω_{q} facilitates fast qubit readout and reset operations.

It is to be noted that qubit readout operation can be performed with the resonant frequency of the tunable readout resonator 120 tuned to some point on the tuning curve 310 other than the low frequency point 312. For example, a qubit readout operation can be performed with the tunable readout resonator 120 tuned to a resonant frequency that falls on a slope of tuning curve 310, such as the third resonant frequency ωᵣ₃ represented by the third point 313 (e.g., a mid-frequency point) on a slope of the tuning curve 310 between the high frequency point 311 and the low frequency point 312. At the third point 313, the third detuning value Δ₃=ωᵣ₃−ω_{q} between tunable readout resonator 120 and the superconducting qubit 110 provides a sufficient increase in the dispersive coupling factor χ to enable a relatively fast readout, while reducing an amount of leakage that occurs during the readout, as compared to higher leakage that can occur when performing a qubit readout operation at low frequency point 312 with the smaller amount of detuning Δ₂ between tunable readout resonator 120 and the superconducting qubit 110.

In this regard, it is to be noted that performing a qubit readout operation with the resonant frequency of the tunable readout resonator 120 tuned to the low frequency point 312 may not be optimal under certain circumstances, where the relatively high amount of leakage can degrade other performance criteria which requires a relatively longer qubit relaxation time T1. As such, a mid-frequency point (e.g., point P3) can be selected for tuning the resonant frequency of the tunable readout resonator 120 to reduce the amount of qubit leakage that occurs during readout. Indeed, in some instances, the superconducting qubit 110 can actually transition to a higher excited state (e.g., second excited state |2 [symbol] ) during readout if the frequency relation between the superconducting qubit 110 and the tunable readout resonator 120 is not advantageous. By utilizing the tunable readout resonator 120, an optimal mid-frequency point can be selected to perform a qubit readout operation where qubit leakage is minimized during the readout operation.

It is to be noted that the quantum systems shown in FIGS. 1A, 1B, and 2 can be designed with various operating parameters, depending on the given application. To provide some illustrative context, in some embodiments, the exemplary quantum systems can be designed based on the following non-limiting exemplary set of operating parameters. For example, for the exemplary tunable readout resonator 120, assuming the fixed resonator 122 comprises a transmission line resonator, the fixed resonator 122 can have a length on the order of millimeters (e.g., 3.5 mm) with an inductance of about 400 nanohenries (nH)/m, and a capacitance of about 150 picofarads (pF)/m, such that the transmission line resonator comprises a fundamental resonant frequency f₀ of about 9.2 GHz (without the tunable element 124). Moreover, assuming that the tunable element 124 comprises an asymmetric SQUID with asymmetric Josephson junctions J1 and J2, the critical current of the asymmetric SQUID can be modulated between (i) a first critical current I_{CS1} of about 0.35 microamperes (μA), when a net magnetic flux bias of Φ=0 threads through the superconducting loop of the asymmetric SQUID, and (ii) a second critical current I_{CS2} of about 1.5 μA when a net magnetic flux bias Φ≅−0.50 Φ₀ threads through the superconducting loop of the asymmetric SQUID.

Furthermore, in an illustrative, non-limiting embodiment, the superconducting qubit 110 can have a fixed transition frequency ω_{q} of about 5 GHz. In addition, the tunable readout resonator 120 can have a highest resonant frequency ωᵣ₁ of 8 GHz, and a lowest resonant frequency ωᵣ₂ of 5.5 GHz, resulting in a detuning value Δ₁=ωᵣ₁−ω_{q}=3 GHz at the high frequency point 311, and a detuning value Δ₂=ωᵣ₂−ω_{q}=0.5 GHz at the low frequency point 312. In addition, assuming that for a readout operation, the tunable readout resonator 120 is tuned to a resonant frequency ωᵣ₃ of 5 GHz (at the mid-frequency point 313), the detuning value Δ₃=ωᵣ₃−ω_{q} for the readout operation would be Δ₃=1.0 GHz. Such exemplary parameters would allow for a 200 ns readout time (or measurement time T_{M}) assuming, e.g., a qubit-resonator coupling of

$$\frac{g}{2 π} = 40 MHz ,$$

a resonator coupling κ=5 MHz, and a quantum efficiency=0.25.

In addition, for a standby (Off) state at the high frequency point 311, the above exemplary set of parameters would provide a dispersive coupling χ=−0.05 MHz, a readout fidelity=0.44, and a Purcel time of 1.2 milliseconds. Further, for reset (On) state at the low frequency point 312, the above exemplary set of parameters would provide a dispersive coupling χ=−1.2 MHz, a readout fidelity=0.9998, and a Purcel time of 0.05 milliseconds. In addition, for read state at the mid-frequency point 313, the above exemplary set of parameters would provide a dispersive coupling χ=−0.36 MHz, a readout fidelity=0.998, and a Purcel time of 0.14 milliseconds.

FIG. 4 illustrates a flow diagram that illustrates a method for controlling a tunable readout resonator to perform qubit readout and qubit reset operations, according to an exemplary embodiment of the disclosure. In particular, FIG. 4 illustrates a control process 400 for frequency tuning a tunable readout resonator into different states for performing qubit readout and reset operations. For illustrative purposes, the process flow of FIG. 4 will be discussed with reference to the exemplary tunable readout resonator 120 and superconducting qubit 110 shown in FIGS. 1A, 1B, and 2, and the exemplary tuning curve shown in FIG. 3. The control process 400 flux-tunes the tunable readout resonator 120 into a first operating state (e.g., standby state) while one or more gate operations are performed on the superconducting qubit 110 (block 401). As noted above, in this state, the resonant frequency of the tunable readout resonator 120 is tuned to the high frequency point 311 (FIG. 3) where the detuning value Δ₁ between the tunable readout resonator and the superconducting qubit 110 is relatively large such that Purcell loss is negligible. The tunable readout resonator 120 will be maintained in the first operating state (e.g., standby state) before performing a qubit readout operation or a qubit reset operation.

When the control process 400 determines to measure the state of the superconducting qubit 110 (affirmative determination in block 402), the control process 400 will flux tune the tunable readout resonator 120 into a second operating state (e.g., readout state) to perform a readout operation (block 403). As noted above, in the readout state, the resonant frequency of the tunable readout resonator 120 is tuned to either the low frequency point 312 to provide a resonator-qubit detuning Δ₂ for the readout operation, or to some mid-frequency point 313 to provide a resonator-qubit detuning Δ₃ for the readout operation. The control process 400 then applies a readout control signal (RF_RO) to the tunable readout resonator 120, with the readout control signal RF_RO having a center frequency that corresponds to the tuned resonant frequency (e.g., ωᵣ₂ or ωᵣ₃) of the tunable readout resonator 120, and then measures a quantum state of the superconducting qubit 110 based on an output readout signal RO (block 404) that is reflected out from tunable readout resonator 120 as a result of the interaction of the qubit-resonator system with the readout control signal RF_RO.

Following the qubit readout operation, a reset operation can be performed to reset the state of the superconducting qubit 110 to a ground state. In some instances, when the readout operation is performed as part of a mid-circuit measurement, the qubit will not be reset (negative determination in block 405), and the tunable readout resonator will be flux-tuned into the first (standby) operating state (block 401) to suppress any further Purcell decay of the qubit energy before a next measurement. It is to be noted that a “mid-circuit measurement” is a specification of a type of measurement which enables a quantum computing system to measure an outcome in the middle of a quantum circuit. In particular, a mid-circuit measurement is a unique feature that allows a given qubit to be selectively measured at some point of execution of a quantum circuit other than the end of the quantum circuit. The mid-circuit measurement is performed using a quantum non-demolition (QND) measurement, as discussed herein.

On the other hand, if the control process 400 determines that the state of the superconducting qubit 110 is to be reset (e.g., via a parametric reset) following the readout operation (affirmative determination in block 405), the control process 400 will proceed to flux tune the readout resonator into a third operating state (e.g., reset state) to perform a parametric reset operation (block 406). As noted above, in the reset state, the resonant frequency of the tunable readout resonator 120 is tuned to the low frequency point 312 to provide a very low resonator-qubit detuning Δ₂ for the reset operation. It is to be noted that the additional tuning operation in block 406 is not needed in instances where the readout operation was performed with the tunable readout resonator 120 tuned at the frequency point 312 and resonator-qubit detuning Δ₂.

The control process 400 performs the parametric reset operation by applying an AC flux bias signal (Flux_Reset) to the tunable element 124 of the tunable readout resonator 120 to modulate the resonant frequency of the tunable readout resonator 120 around the low frequency point 312 to reset the state of the superconducting qubit 110 (block 407). For example, assuming that the resonator-qubit detuning Δ₂ is 500 MHz, the parametric reset operation can be performed by driving the tunable element 124 of the tunable readout resonator 120 with an AC drive signal Flux_Reset having a frequency which correspond to the low resonator-qubit detuning Δ₂ (e.g., 500 MHz) or one-half Δ₂ (e.g., 250 MHz) to reset the state of the superconducting qubit 110.

The Flux_Reset signal modulates the magnetic flux that is threaded through the superconducting loop of the tunable element 124, which results in modulating the resonant frequency of the tunable readout resonator 120 (around the lower frequency point 312) in a way that causes a parametric swapping of an excited state of the superconducting qubit 110 into the tunable readout resonator 120 (which then dissipates the energy), to thereby reset the state of the superconducting qubit 110 to a ground state. Due to the symmetric nature of the tuning curve around the low frequency point 312 (and the first order insensitivity to flux noise at the low frequency point 312), frequency doubling is achieved when driving symmetrically around the low frequency point 312, thus, it can be driven at half the transition frequency, allowing for more aggressive filtering of the drive line.

Following the qubit reset, the control process 400 proceeds to flux tune the tunable readout resonator 120 back into the standby state (return to block 401), where the resonant frequency of the tunable readout resonator 120 is tuned to the high frequency point 311 with a large qubit-resonator detuning Δ₂ which significant suppresses Purcell loss, allowing further gate operations to be performed on the superconducting qubit 110.

It is to be noted that in some embodiments, the parametric reset operation applied in block 407 can include multiple sequential reset operations that are performed using different parametric tones that are configured to parametrically reset higher leakage states of the superconducting qubit 110. For example, a Flux_Reset signal can be configured to modulate the resonant frequency of the tunable readout resonator 120 around the low frequency point 312 in a way that causes a second excited state |2 [symbol] (or a higher excited state) to be swapped from the superconducting qubit 110 into the tunable readout resonator 120 and dissipated, to thereby relax the superconducting qubit 110.

Moreover, in other embodiments, the Purcell loss of the superconducting qubit 110 can be made large enough at the low frequency point 312 such that a parametric reset is not necessary. In this instance, if the control process 400 determines that the state of the superconducting qubit 110 is to be reset following the readout operation, the control process 400 can proceed to flux tune the tunable readout resonator into the third operating state (e.g., reset state) where the resonant frequency of the tunable readout resonator 120 is tuned to the low frequency point 312. The low resonator-qubit detuning Δ₂ at the low frequency point 312 can provide a high enough Purcell decay rate which causes relaxation of the superconducting qubit 110 after a relatively short amount of time.

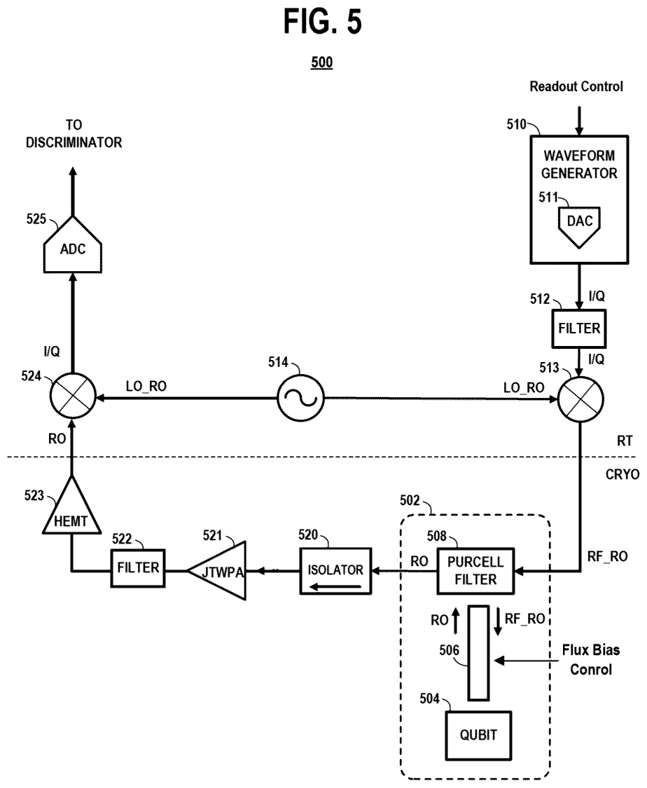

FIG. 5 schematically illustrates readout circuitry of a quantum processing system in which tunable readout resonators are implemented to perform qubit readout and qubit reset operations, according to an exemplary embodiment of the disclosure. More specifically, FIG. 5 schematically illustrates qubit readout circuitry 500 of a quantum computing system which is configured to readout a quantum state of at least one superconducting qubit. For example, the qubit readout circuitry 500 comprises a qubit-resonator device 502 comprising a superconducting qubit 504, a tunable readout resonator 506, and an optional Purcell filter 508. In some embodiments, the tunable readout resonator 506 comprises a flux tunable readout resonator which is implemented using the same or similar architecture as the tunable readout resonator 120 shown in FIGS. 1A, 1B, and 2. In this regard, as schematically shown in FIG. 5, the tunable readout resonator 506 is responsive to flux bias control signals to tune the resonant frequency of the tunable readout resonator 506 as desired for different operating modes, e.g., standby mode, qubit readout mode, qubit reset mode, using techniques as discussed above.

The qubit readout circuitry 500 further comprises control circuitry that is configured to generate an RF readout control signal (RF_RO) to readout the state of the superconducting qubit 504 using a dispersive readout scheme which enables a quantum non-demolition measurement of the state of the superconducting qubit 504 to preserve the state of the superconducting qubit 504. For example, the qubit readout circuitry 500 comprises a control signal chain which comprises a waveform generator 510 (or pulse envelope generator) which comprises digital-to-analog (DAC) circuitry 511, low-pass filter circuitry 512, a first I/Q mixer 513 (upconverter mixer), and a local oscillator (LO) signal generator 514. In addition, the qubit readout circuitry 500 comprises readout signal chain which comprises an isolator circuit 520, a Josephson junction traveling wave parametric amplifier (JTWPA) circuit 521, a filter 522, a high-electron-mobility-transistor (HEMT) amplifier 523, a second I/Q mixer 524, and analog-to-digital converter (ADC) circuitry 525, which outputs digital readout signals to a hardware or software-based discriminator to determine a readout state of the superconducting qubit 504.

The waveform generator 510 is configured to generate and output analog I and Q control signals with a given type of pulse envelope (e.g., Gaussian square pulse envelope) for qubit state readout, in response to a readout control signal. The analog I and Q control pulses are filtered by the low-pass filter circuitry 512. The filtered analog control I and Q control pulses are applied to the first I/Q mixer 513, along with an LO signal (LO_RO) that is generated by the LO signal generator 514, to generate an RF readout control pulse RF_RO. In particular, the I/Q mixer 513 is configured mix the analog I and Q control pulses with the LO_Q signals of a given LO frequency (e.g., 7 GHz) to perform I/Q modulation and upconversion and/or downconversion using known techniques (e.g., single sideband modulation) to generate the RF readout control pulse RF_RO.

The RF readout control signal RF_RO is applied to an input port of the Purcell filter 508, and then coupled to the tunable readout resonator 506. The tunable readout resonator 506 is capacitively coupled to the superconducting qubit 504, thereby providing a qubit/resonator system. As noted above, in some embodiments, the tunable readout resonator 506 comprises, e.g., a fixed resonator (e.g., a quarter-wavelength coplanar waveguide resonator) that is shunted by a tunable element (e.g., an asymmetric SQUID) with a tunable inductance, such as discussed above. For a readout operation, the center frequency of the RF readout control signal RF_RO corresponds to the resonant frequency of the tunable readout resonator 506 which is tuned to desired resonant frequency (e.g., low frequency point 312, or mid-frequency point 313, FIG. 3) to perform a dispersive qubit readout operation.

As noted above, in the dispersive regime of qubit-resonator coupling, the RF readout control signal RF_RO (with the requisite frequency tone, pulse envelope shape, and pulse duration) interacts with the given qubit-resonator device 502 in a manner which results in the generation of a resulting readout signal RO that is reflected out from the tunable readout resonator 506, wherein the readout signal RO comprises information (e.g., phase and/or amplitude) that is qubit-state dependent. In other words, the dispersive readout process yields an RF readout signal RO having a state-dependent phasor response, which is analyzed to discriminate the quantum state of the superconducting qubit 504.

The readout signal RO output from the tunable readout resonator 506 is coupled to the Purcell filter 508, and then applied to the readout signal chain. The Purcell filter 508 is designed, for example, to pass at the frequency of the readout signal RO while blocking the transmission of energy at the qubit frequency, to enhance the qubit lifetime, and perform other functions as discussed above in conjunction with FIG. 2.

The readout signal RO is coupled out to the readout signal chain where the readout signal RO flows through the isolator circuit 520 and applied to an input port of the JTWPA circuit 521. The JTWPA circuit 521 amplifies the readout signal RO. The amplified readout signal RO, which is output from the JTWPA circuit 521, is transmitted along a signal chain comprising the filter 522 and another optional isolator circuit, amplified by the HEMT amplifier 523, and applied to an input of the second I/Q mixer 524. The second I/Q mixer 524 mixes the RF readout signal RO with the LO_RO signal to perform a down conversion operation where the RF readout signal RO is down converted and split into analog I and Q signals. The analog I and Q signals are input to the ADC circuitry 525 and sampled by the ADC circuitry 525 to generate respective digital I and Q signals that are indicative of the amplitude and phase of the readout signal RO. A discriminator analyzes the digital I and Q signals to discriminate the measured quantum state of the superconducting qubit 504 based on the amplitude and phase components of the readout signal RO.

It is to be understood that FIG. 5 is an exemplary non-limiting embodiment which schematically illustrates a high-level schematic illustration of readout control circuitry. The qubit readout circuitry 500 and readout signal chain can be implemented using other components and configurations. For example, in some embodiments, when the Purcell filter 508 is not implemented, a circulator of feedline can be implemented in FIG. 5 in place of the Purcell filter block. Further, a frequency-multiplexed readout system (which implements frequency domain multiplexing) can be utilized to scale-up a readout chain in a quantum computing system for reading the quantum states of superconducting qubits in relatively large superconducting quantum computers. In a frequency-multiplexed readout system, multiple readout resonators (with different resonance frequencies) are coupled to separate qubits and commonly coupled to a communication bus. The communication bus is configured to allow the transmission of multiple readout signals with readout frequencies which match the resonance frequencies of the readout resonators, and, thus simultaneously read out the quantum states of multiple qubits using one input and one output line.

FIG. 6 schematically illustrates a quantum computing system 600 which comprises a quantum computing platform 610, a control system 620, and a quantum processor 630. In some embodiments, the quantum computing platform 610 implements a software platform that is configured to program a quantum computer to execute quantum computing algorithms 612 which are implemented using, e.g., quantum circuits which define computational routings consisting of coherent quantum operations on quantum data, such as qubits. In addition, in some embodiments, the control system 620 comprises a multi-channel arbitrary waveform generator 622, a quantum bit readout control circuitry 624 (e.g., FIG. 6), and flux bias control signal generator 626. The quantum processor 630 comprises one or more solid-state quantum chips which comprise, e.g., a superconducting qubit array 632 with flux-tunable readout resonators, and a network of control lines 634 including qubit drive lines, qubit coupler drive lines, flux bias control lines, qubit readout I/O lines, and other circuit QED components that may be needed for a given application or quantum system configuration.

In some embodiments, the control system 620 and the quantum processor 630 are disposed in a dilution refrigeration system 640 which can generate cryogenic temperatures that are sufficient to operate components of the control system 620 for quantum computing applications. For example, the quantum processor 630 may need to be cooled down to near-absolute zero, e.g., 10-15 millikelvin (mK), to allow the superconducting qubits to exhibit quantum behaviors. In some embodiments, the dilution refrigeration system 640 comprises a multi-stage dilution refrigerator where the components of the control system 620 can be maintained at different cryogenic temperatures, as needed. For example, while the quantum processor 630 may need to be cooled down to, e.g., 10-15 mK, the circuit components of the control system 620 may be operated at cryogenic temperatures greater than 10-15 mK (e.g., cryogenic temperatures in a range of 3K-4K), depending on the configuration of the quantum computing system. In some embodiments, the entirety of the control system 620, or some components thereof, are disposed in a room temperature environment.

In some embodiments, the superconducting qubit array 632 comprises a quantum system of superconducting qubits and associated tunable readout resonators, superconducting qubit couplers, and other components commonly utilized to support quantum processing using qubits. The number of superconducting qubits of the superconducting qubit array 632 can be on the order of tens, hundreds, thousands, or more, etc. The network of control lines 634 is configured to apply microwave control signals to superconducting qubits and coupler circuitry in the superconducting qubit array 632 to perform various types of gate operations, e.g., single-gate operations, entanglement gate operations, perform error correction operations, etc., as well as read the quantum states of the superconducting qubits. For example, microwave control pulses are applied to the qubit drive lines of respective superconducting qubits to change the quantum state of the superconducting qubits (e.g., change the quantum state of a given qubit between the ground state and excited state, or to a superposition state) when executing quantum information processing algorithms.

Furthermore, as noted above, network of control lines 634 comprise flux bias control lines that are configured to apply flux bias control signals to the tunable readout resonators that are coupled to respective superconducting qubits in the superconducting qubit array 632 to flux tune the tunable readout resonators in desired states for different modes of operation (standby mode, qubit readout mode, qubit reset mode). The network of control lines 634 is coupled to the control system 620 through a suitable hardware input/output (I/O) interface, which couples I/O signals between the control system 620 and the quantum processor 630. For example, the hardware I/O interface may comprise various types of hardware and components, such as RF cables, wiring, RF elements, optical fibers, heat exchanges, filters, amplifiers, isolators, etc.

In some embodiments, the multi-channel arbitrary waveform generator (AWG) 622 and other suitable microwave pulse signal generators are configured to generate the microwave control pulses that are applied to the qubit drive lines, and the coupler drive lines to control the operation of the superconducting qubits and associated qubit coupler circuitry, when performing various gate operations to execute a given certain quantum information processing algorithm. In some embodiments, the multi-channel AWG 622 comprises a plurality of AWG channels, which control respective superconducting qubits within the superconducting qubit array 632 of the quantum processor 630. In some embodiments, each AWG channel comprises a baseband signal generator, a digital-to-analog converter (DAC) stage, a filter stage, a modulation stage, an impedance matching network, and a phase-locked loop system to generate LO signals (e.g., quadrature LO signals LO_I and LO_Q) for the respective modulation stages of the respective AWG channels.

In some embodiments, the multi-channel AWG 622 comprises a quadrature AWG system which is configured to process quadrature signals, wherein a quadrature signal comprises an in-phase (I) signal component, and a quadrature-phase (Q) signal component. In each AWG channel the baseband signal generator is configured to receive baseband data as input (e.g., from the quantum computing platform), and generate digital quadrature signals I and Q which represent the input baseband data. In this process, the baseband data that is input to the baseband signal generator for a given AWG channel is separated into two orthogonal digital components including an in-phase (I) baseband component and a quadrature-phase (Q) baseband component. The baseband signal generator for the given AWG channel will generate the requisite digital quadrature baseband IQ signals which are needed to generate an analog waveform (e.g., sinusoidal voltage waveform) with a target center frequency that is configured to operate or otherwise control a given quantum bit that is coupled to the output of the given AWG channel.

The DAC stage for the given AWG channel is configured to convert a digital baseband signal (e.g., a digital IQ signal output from the baseband signal generator) to an analog baseband signal (e.g., analog baseband signals I(t) and Q(t)) having a baseband frequency. The filter stage for the given AWG channel is configured to filter the IQ analog signal components output from the DAC stage to thereby generate filtered analog IQ signals. The modulation stage for the given AWG channel is configured to perform analog IQ signal modulation (e.g., single-sideband (SSB) modulation) by mixing the filtered analog signals I(t) and Q(t), which are output from the filter stage, with quadrature LO signals (e.g., an in-phase LO signal (LO_I) and a quadrature-phase LO signal (LO_Q)) to generate and output an analog RF signal (e.g., a single-sideband modulated RF output signal). In some embodiments, the quantum bit readout control circuitry 624 is implemented based on the readout circuit architecture as schematically shown in FIG. 6.

The quantum computing platform 610 comprises a software and hardware platform which comprises various software layers that are configured to perform various functions, including, but not limited to, generating and implementing various quantum applications using suitable quantum programming languages, configuring and implementing various quantum gate operations, compiling quantum programs into a quantum assembly language, implementing and utilizing a suitable quantum instruction set architecture (ISA), performing calibration operations to calibrate the quantum circuit elements and gate operations, etc. In addition, the quantum computing platform 610 comprises a hardware architecture of processors, memory, etc., which is configured to control the execution of quantum applications, and interface with the control system 620 to (i) generate digital control signals that are converted to analog microwave control signals by the control system 620, to control operations of the quantum processor 630 when executing a given quantum application, and (ii) to obtain and process digital signals received from the control system 620, which represent the processing results generated by the quantum processor 630 when executing various gate operations for a given quantum application.

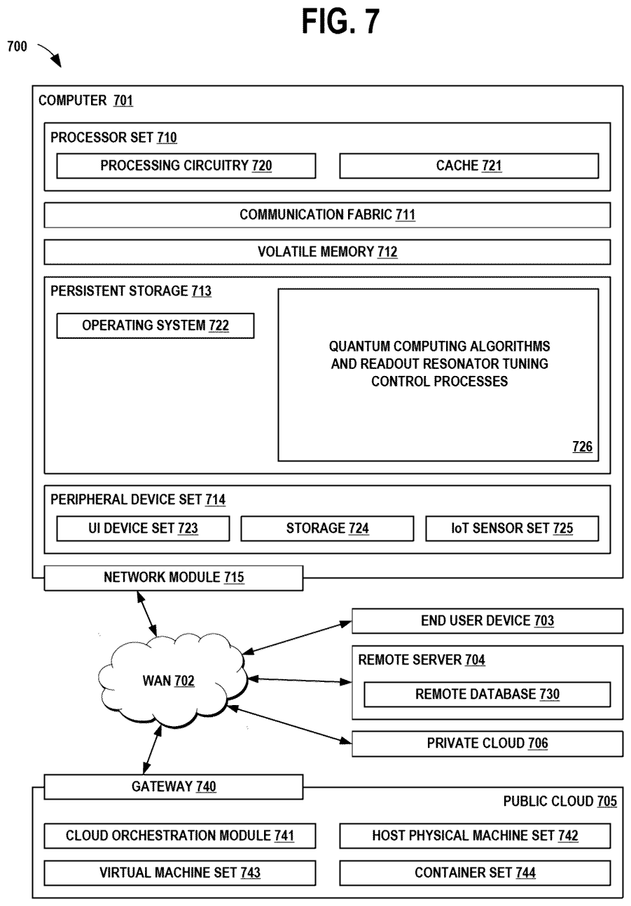

In some exemplary embodiments, the quantum computing platform 610 of the quantum computing system 600 may be implemented using any suitable computing system architecture (e.g., as shown in FIG. 7) which is configured to implement methods to support quantum computing operations by executing computer readable program instructions that are embodied on a computer program product which includes a computer readable storage medium (or media) having such computer readable program instructions thereon for causing a processor to perform control methods as discussed herein.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random-access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

FIG. 7 schematically illustrates an exemplary architecture of a computing environment 700 for hosting a quantum computing platform, according to an exemplary embodiment of the disclosure. The computing environment 700 of FIG. 7 illustrate an exemplary environment for the execution of at least some computer code (block 726) involved in performing quantum computing algorithms and performing readout resonator tuning control processes to tune the resonant frequencies of tunable readout resonators as desired for different operating modes, e.g., standby mode, qubit readout mode, qubit reset mode, using techniques as discussed above (e.g., FIGS. 3, 4, and 5). In addition to block 726, computing environment 700 includes, for example, computer 701, wide area network (WAN) 702, end user device (EUD) 703, remote server 704, public cloud 705, and private cloud 706. In this embodiment, computer 701 includes processor set 710 (including processing circuitry 720 and cache 721), communication fabric 711, volatile memory 712, persistent storage 713 (including operating system 722 and block 726, as identified above), peripheral device set 714 (including user interface (UI), device set 723, storage 724, and Internet of Things (IoT) sensor set 725), and network module 715. Remote server 704 includes remote database 730. Public cloud 705 includes gateway 740, cloud orchestration module 741, host physical machine set 742, virtual machine set 743, and container set 744.

Computer 701 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 730. As is well understood in the art of computer technology, and depending upon the technology, performance of a computer-implemented method may be distributed among multiple computers and/or between multiple locations. On the other hand, in this presentation of computing environment 700, detailed discussion is focused on a single computer, specifically computer 701, to keep the presentation as simple as possible. Computer 701 may be located in a cloud, even though it is not shown in a cloud in FIG. 7. On the other hand, computer 701 is not required to be in a cloud except to any extent as may be affirmatively indicated.

Processor set 710 includes one, or more, computer processors of any type now known or to be developed in the future. Processing circuitry 720 may be distributed over multiple packages, for example, multiple, coordinated integrated circuit chips. Processing circuitry 720 may implement multiple processor threads and/or multiple processor cores. Cache 721 is memory that is located in the processor chip package(s) and is typically used for data or code that should be available for rapid access by the threads or cores running on processor set 710. Cache memories are typically organized into multiple levels depending upon relative proximity to the processing circuitry. Alternatively, some, or all, of the cache for the processor set may be located “off chip.” In some computing environments, processor set 710 may be designed for working with qubits and performing quantum computing.

Computer readable program instructions are typically loaded onto computer 701 to cause a series of operational steps to be performed by processor set 710 of computer 701 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 721 and the other storage media discussed below. The program instructions, and associated data, are accessed by processor set 710 to control and direct performance of the inventive methods. In computing environment 700, at least some of the instructions for performing the inventive methods may be stored in block 726 in persistent storage 713.

Communication fabric 711 is the signal conduction paths that allow the various components of computer 701 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 712 is any type of volatile memory now known or to be developed in the future. Examples include dynamic type random access memory (RAM) or static type RAM. Typically, the volatile memory is characterized by random access, but this is not required unless affirmatively indicated. In computer 701, the volatile memory 712 is located in a single package and is internal to computer 701, but, alternatively or additionally, the volatile memory may be distributed over multiple packages and/or located externally with respect to computer 701.

Persistent storage 713 is any form of non-volatile storage for computers that is now known or to be developed in the future. The non-volatility of this storage means that the stored data is maintained regardless of whether power is being supplied to computer 701 and/or directly to persistent storage 713. Persistent storage 713 may be a read only memory (ROM), but typically at least a portion of the persistent storage allows writing of data, deletion of data and re-writing of data. Some familiar forms of persistent storage include magnetic disks and solid-state storage devices. Operating system 722 may take several forms, such as various known proprietary operating systems or open source Portable Operating System Interface type operating systems that employ a kernel. The code included in block 726 typically includes at least some of the computer code involved in performing the inventive methods.

Peripheral device set 714 includes the set of peripheral devices of computer 701. Data communication connections between the peripheral devices and the other components of computer 701 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 723 may include components such as a display screen, speaker, microphone, wearable devices (such as goggles and smart watches), keyboard, mouse, printer, touchpad, game controllers, and haptic devices. Storage 724 is external storage, such as an external hard drive, or insertable storage, such as an SD card. Storage 724 may be persistent and/or volatile. In some embodiments, storage 724 may take the form of a quantum computing storage device for storing data in the form of qubits. In embodiments where computer 701 is required to have a large amount of storage (for example, where computer 701 locally stores and manages a large database) then this storage may be provided by peripheral storage devices designed for storing very large amounts of data, such as a storage area network (SAN) that is shared by multiple, geographically distributed computers. IoT sensor set 725 is made up of sensors that can be used in Internet of Things applications. For example, one sensor may be a thermometer and another sensor may be a motion detector.

Network module 715 is the collection of computer software, hardware, and firmware that allows computer 701 to communicate with other computers through WAN 702. Network module 715 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 715 are performed on the same physical hardware device. In other embodiments (for example, embodiments that utilize software-defined networking (SDN)), the control functions and the forwarding functions of network module 715 are performed on physically separate devices, such that the control functions manage several different network hardware devices. Computer readable program instructions for performing the inventive methods can typically be downloaded to computer 701 from an external computer or external storage device through a network adapter card or network interface included in network module 715.

WAN 702 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 703 is any computer system that is used and controlled by an end user (for example, a customer of an enterprise that operates computer 701), and may take any of the forms discussed above in connection with computer 701. EUD 703 typically receives helpful and useful data from the operations of computer 701. For example, in a hypothetical case where computer 701 is designed to provide a recommendation to an end user, this recommendation would typically be communicated from network module 715 of computer 701 through WAN 702 to EUD 703. In this way, EUD 703 can display, or otherwise present, the recommendation to an end user. In some embodiments, EUD 703 may be a client device, such as thin client, heavy client, mainframe computer, desktop computer and so on.

Remote server 704 is any computer system that serves at least some data and/or functionality to computer 701. Remote server 704 may be controlled and used by the same entity that operates computer 701. Remote server 704 represents the machine(s) that collect and store helpful and useful data for use by other computers, such as computer 701. For example, in a hypothetical case where computer 701 is designed and programmed to provide a recommendation based on historical data, then this historical data may be provided to computer 701 from remote database 730 of remote server 704.

Public cloud 705 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 705 is performed by the computer hardware and/or software of cloud orchestration module 741. The computing resources provided by public cloud 705 are typically implemented by virtual computing environments that run on various computers making up the computers of host physical machine set 742, which is the universe of physical computers in and/or available to public cloud 705. The virtual computing environments (VCEs) typically take the form of virtual machines from virtual machine set 743 and/or containers from container set 744. It is understood that these VCEs may be stored as images and may be transferred among and between the various physical machine hosts, either as images or after instantiation of the VCE. Cloud orchestration module 741 manages the transfer and storage of images, deploys new instantiations of VCEs and manages active instantiations of VCE deployments. Gateway 740 is the collection of computer software, hardware, and firmware that allows public cloud 705 to communicate through WAN 702.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 706 is similar to public cloud 705, except that the computing resources are only available for use by a single enterprise. While private cloud 706 is depicted as being in communication with WAN 702, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 705 and private cloud 706 are both part of a larger hybrid cloud.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A device, comprising:
a superconducting quantum bit; and
a tunable readout resonator coupled to the superconducting quantum bit and comprising a fixed resonator and a tunable element which is coupled to the fixed resonator and which is configured for flux-tuning the tunable readout resonator into at least one of a first state and a second state, the tunable element comprising a superconducting loop which comprises at least two asymmetric Josephson junctions;
wherein in the first state, the tunable readout resonator comprises a first resonant frequency that differs from a transition frequency of the superconducting quantum bit by a first detuning value; and
wherein in the second state, the tunable readout resonator comprises a second resonant frequency that differs from the transition frequency of the superconducting quantum bit by a second detuning value, which is less than the first detuning value.

2. The device of claim 1, wherein the fixed resonator comprises one of a transmission line resonator and a lumped element resonator.

3. The device of claim 1, wherein the tunable element comprises a first Josephson junction having a first critical current, and a second Josephson junction having a second critical current, which is different from the first critical current.

4. The device of claim 1, wherein in the first state, the first detuning value is configured to suppress energy leakage from the superconducting quantum bit through the tunable readout resonator into a transmission line coupled to the tunable readout resonator.

5. The device of claim 1, wherein in the second state, the second detuning value is configured to increase a dispersive coupling between the superconducting quantum bit and the tunable readout resonator to perform a dispersive readout operation to readout a state of the superconducting quantum bit.

6. The device of claim 1, wherein in the second state, the second detuning value is configured to increase a coupling between the superconducting quantum bit and the tunable readout resonator to enable a parametric reset of the superconducting quantum bit by applying an alternating current drive signal to the tunable element of the tunable readout resonator.

7. The device of claim 1, wherein in the second state, the second detuning value is configured to increase a coupling between the superconducting quantum bit and the tunable readout resonator to increase energy leakage from the superconducting quantum bit through the tunable readout resonator into a transmission line coupled to the tunable readout resonator and thereby reset the superconducting quantum bit.

8. The device of claim 1, wherein the tunable element is configured for flux-tuning the tunable readout resonator into a third state in which the tunable readout resonator comprises a third resonant frequency that is detuned from a transition frequency of the superconducting quantum bit by a third detuning value, wherein the third detuning value is less than the first detuning value and greater than the second detuning value.

9. The device of claim 1, further comprising a Purcell filter coupled between the tunable readout resonator and an input/output transmission line, wherein in the first state, the first resonant frequency of the tunable readout resonator is in a stop band of the Purcell filter.

10. A system, comprising:
a quantum processor comprising superconducting quantum bits and tunable readout resonators coupled to respective ones of the superconducting quantum bits; and
a control system configured to generate control signals for controlling the superconducting quantum bits and for controlling the tunable readout resonators;
wherein at least one tunable readout resonator coupled to a given superconducting quantum bit comprises a fixed resonator and a tunable element which is coupled to the fixed resonator and which is responsive to the control signals from the control system to flux tune the at least one tunable readout resonator into at least one of a first state and a second state, the tunable element comprising a superconducting loop which comprises at least two asymmetric Josephson junctions;
wherein in the first state, the at least one tunable readout resonator comprises a first resonant frequency which differs from a transition frequency of the given superconducting quantum bit by a first detuning value; and
wherein in the second state, the at least one tunable readout resonator comprises a second resonant frequency which differs from the transition frequency of the given superconducting quantum bit by a second detuning value, which is less than the first detuning value.

11. The system of claim 10, wherein the fixed resonator comprises one of a transmission line resonator and a lumped element resonator.

12. The system of claim 10, wherein the tunable element comprises a first Josephson junction having a first critical current, and a second Josephson junction having a second critical current, which is different from the first critical current.

13. The system of claim 10, wherein:
in the first state, the first detuning value is configured to suppress energy leakage from the given superconducting quantum bit through the at least one tunable readout resonator into a transmission line coupled to the at least one tunable readout resonator; and
in the second state, the second detuning value is configured to increase a dispersive coupling between the given superconducting quantum bit and the at least one tunable readout resonator to perform a dispersive readout operation to readout a state of the given superconducting quantum bit.

14. The system of claim 10, wherein in the second state, the second detuning value is configured to increase a coupling between the given superconducting quantum bit and the at least one tunable readout resonator to enable a parametric reset of the given superconducting quantum bit by the control system applying an alternating current drive signal to the tunable element of the at least one tunable readout resonator.

15. The system of claim 10, wherein in the second state, the second detuning value is configured to increase a coupling between the given superconducting quantum bit and the at least one tunable readout resonator to increase energy leakage from the given superconducting quantum bit through the at least one tunable readout resonator into a transmission line coupled to the at least one tunable readout resonator and thereby reset the given superconducting quantum bit.

16. The system of claim 10, further comprising a Purcell filter coupled between the at least one tunable readout resonator and an input/output transmission line, wherein in the first state, the first resonant frequency of the at least one tunable readout resonator is in a stop band of the Purcell filter.

17. A method, comprising:
applying a control signal to a tunable readout resonator which is coupled to a superconducting quantum bit, the tunable readout resonator comprising a fixed resonator and a tunable element which is coupled to the fixed resonator and which is responsive to the control signal to flux-tune the tunable readout resonator into at least one of a first state and a second state, the tunable element comprising a superconducting loop which comprises at least two asymmetric Josephson junctions;
wherein in the first state, the tunable readout resonator comprises a first resonant frequency which differs from a transition frequency of the superconducting quantum bit by a first detuning value; and
wherein in the second state, the tunable readout resonator comprises a second resonant frequency which differs from the transition frequency of the superconducting quantum bit by a second detuning value, which is less than the first detuning value.

18. The method of claim 17, wherein applying the control signal to the tunable readout resonator comprises:
applying a first flux bias control signal to place the tunable element in a first inductance state to cause the tunable readout resonator to have the first resonant frequency; and
applying a second flux bias control signal to place the tunable element in a second inductance state to cause the tunable readout resonator to have the second resonant frequency, wherein the second resonant frequency is less than the first resonant frequency.

19. The method of claim 17, further comprising performing a gate operation on the superconducting quantum bit while the tunable readout resonator is in the first state, wherein in the first state, the first detuning value is configured to suppress energy leakage from the superconducting quantum bit through the tunable readout resonator into a transmission line coupled to the tunable readout resonator.

20. The method of claim 17, further comprising performing a dispersive readout operation to readout a state of the superconducting quantum bit, while the tunable readout resonator is in the second state, wherein in the second state, the second detuning value is configured to increase a dispersive coupling between the superconducting quantum bit and the tunable readout resonator to perform the dispersive readout operation.
